(19) United States
(12) Patent Application Publication
(10) Pub. No.: US 2024/0339383 A1
(43) Pub. Date: Oct. 10, 2024

(54) ELECTRONIC DEVICE

(71) Applicant: Advanced Semiconductor Engineering, Inc., Kaohsiung (TW)

(72) Inventors: Ko-Pu WU, Taoyuan City (TW); Chih-Hung HSU, Taoyuan City (TW); Chin Li HUANG, Taoyuan City (TW); Chieh-Yin LIN, Taoyuan City (TW); Yuan-Chun CHEN, Taoyuan City (TW); Kai-Sheng PAI, Taoyuan City (TW)

(73) Assignee: Advanced Semiconductor Engineering, Inc., Kaohsiung (TW)

(21) Appl. No.: 18/132,351

(22) Filed: Apr. 7, 2023

(51) Int. Cl. H01L 23/495

(52) U.S. Cl. CPC H01L 23/49548; H01L 23/3121; H01L 23/49513; H01L 24/29; H01L 24/32; H01L 24/48; H01L 24/73; H01L 2224/29139; H01L 2224/29147; H01L 2224/29155; H01L 2224/29193; H01L 2224/32245; H01L 2224/48091; H01L 2224/48245; H01L 2224/73265

(57) ABSTRACT

An electronic device and a method of manufacturing an electronic device are provided. The electronic device includes an electronic component, a carrier, and a lead. The electronic component has a lateral surface. The carrier supports the electronic component. The lead is electrically connected to the electronic component and disposed adjacent to the lateral surface of the electronic component. The carrier and the lead are configured to block an electromagnetic wave between the electronic component and an external of the electronic device.

### BACKGROUND

### 1. Field of the Disclosure

The present disclosure relates to an electronic device and a method for manufacturing the same.

### 2. Description of the Related Art

A Quad Flat No-Lead (QFN) package may include an additional metal layer to provide electromagnetic shielding. However, the effect of the electromagnetic shielding is not satisfactory, such that a device in the QFN package may be severely influenced by unwanted electromagnetic waves from the environment. Furthermore, the formation of the additional metal layer would increase the manufacturing complexity and the cost.

### SUMMARY

In some embodiments, an electronic device includes an electronic component, a carrier, and a lead. The electronic component has a lateral surface. The carrier supports the electronic component. The lead is electrically connected to the electronic component and disposed adjacent to the lateral surface of the electronic component. The carrier and the lead are configured to block an electromagnetic wave between the electronic component and an external of the electronic device.

In some embodiments, an electronic device includes an encapsulant and a conductive structure. The conductive structure is encapsulated by the encapsulant. The conductive structure includes a carrier, a connecting element, and a lead. The connecting element supports the carrier and has a first upper surface exposed from the encapsulant. The lead is spaced apart from the connecting element and has a first upper surface exposed from the encapsulant. An area of the first supper surface of the connecting element is less than an area of the first upper surface of the lead.

In some embodiments, an electronic device includes an electronic component, an encapsulant, and a lead. The encapsulant encapsulates the electronic component and has a top surface and a lateral surface. The lead is disposed at a side of the electronic component. The lead has a top surface substantially aligned with the top surface of the encapsulant, a lateral surface substantially aligned with the lateral surface of the encapsulant, a curved surface extending between the top surface of the lead and the lateral surface of the lead.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a bottom view of an electronic device according to some embodiments of the present disclosure.

FIG. 1A illustrates a top view of an electronic device according to some embodiments of the present disclosure.

FIG. 1B illustrates a cross-sectional view of an electronic device according to some embodiments of the present disclosure.

FIG. 1B-1 illustrates a cross-sectional view of an electronic device according to some embodiments of the present disclosure.

FIG. 1C illustrates a cross-sectional view of an electronic device according to some embodiments of the present disclosure.

FIG. 1D illustrates a cross-sectional view of an electronic device according to some embodiments of the present disclosure.

FIG. 1E illustrates a perspective view of an electronic device according to some embodiments of the present disclosure.

FIG. 1F illustrates a perspective view of an electronic device according to some embodiments of the present disclosure.

FIG. 1G illustrates a plot of the intensity of electromagnetic waves versus frequency according to some embodiments of the present disclosure.

FIG. 1H illustrates a cross-sectional view of an electronic device according to some embodiments of the present disclosure.

FIG. 2A illustrates a cross-sectional view of an electronic device according to some embodiments of the present disclosure.

FIG. 2B illustrates a cross-sectional view of an electronic device according to some embodiments of the present disclosure.

FIG. 3A illustrates a cross-sectional view of an electronic device according to some embodiments of the present disclosure.

FIG. 3B illustrates a cross-sectional view of an electronic device according to some embodiments of the present disclosure.

FIG. 4A-1, FIG. 4A-2, FIG. 4A-3, FIG. 4A-4, FIG. 4A-5, FIG. 4B-1, 4B-2, FIG. 4C-1, 4C-2, FIG. 4D-1, FIG. 4D-2, FIG. 4D-3, FIG. 4D-4, FIG. 4E-1, 4E-2, FIG. 4F-1, 4F-2, FIGS. 4G-1, and 4G-2 illustrate one or more stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

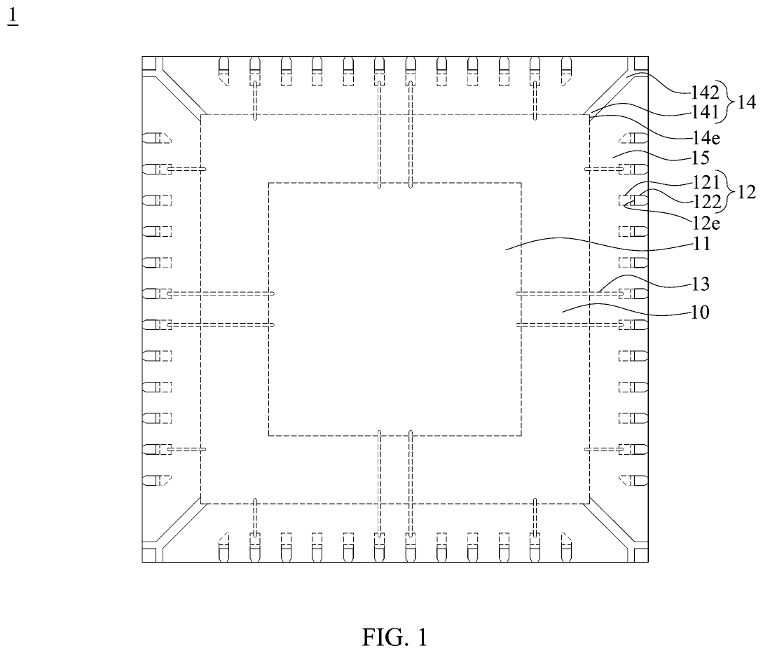

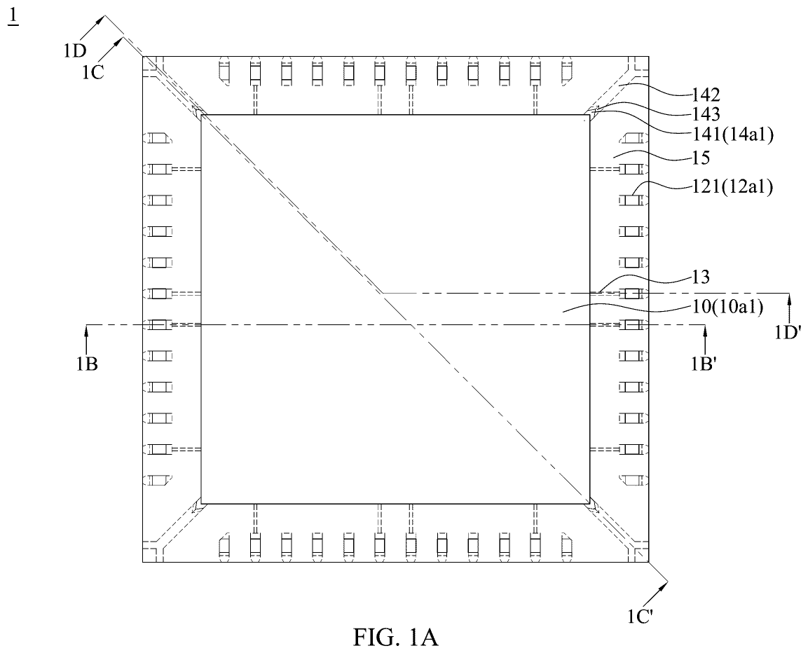

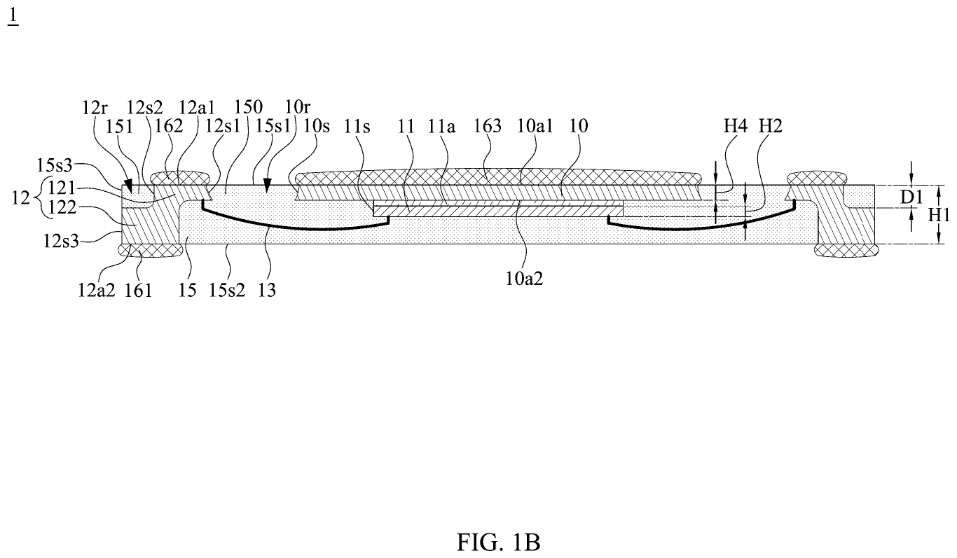

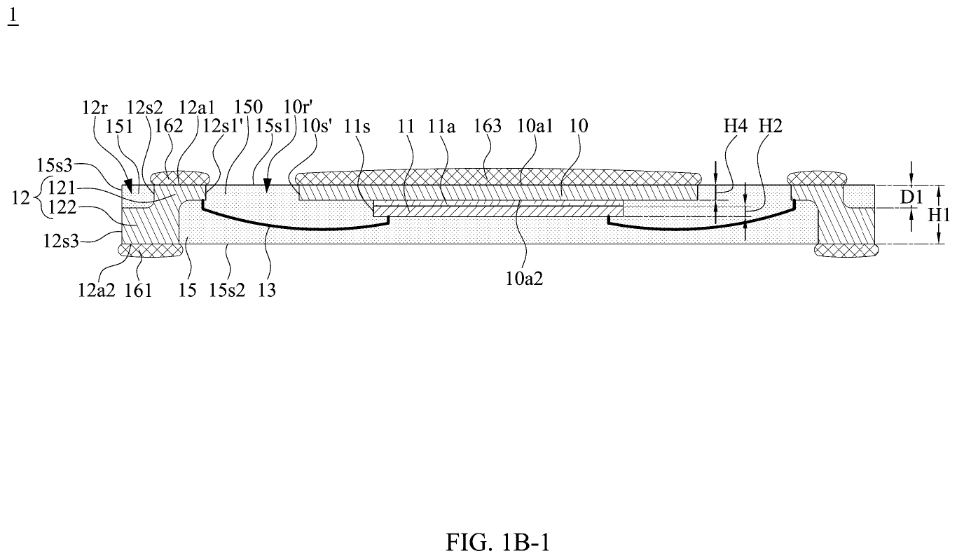

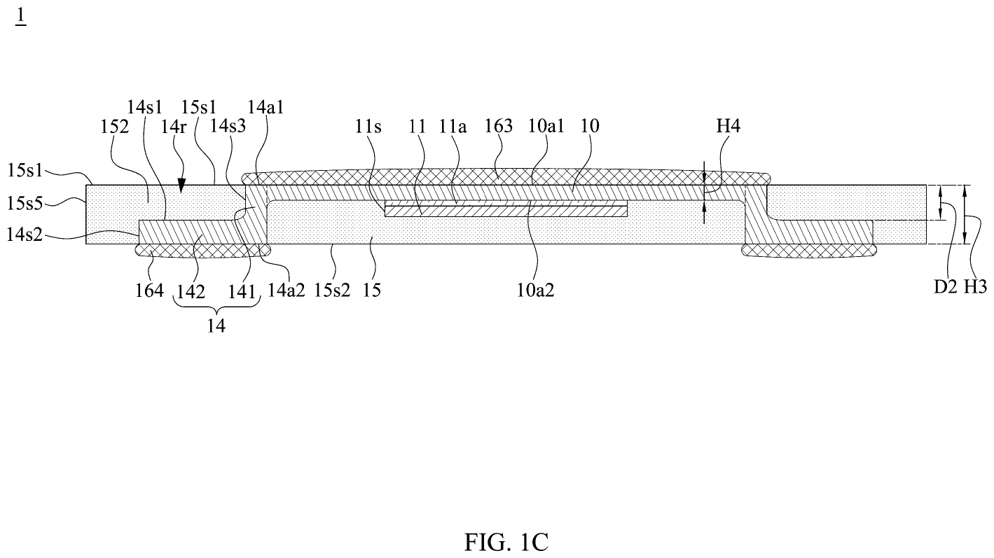

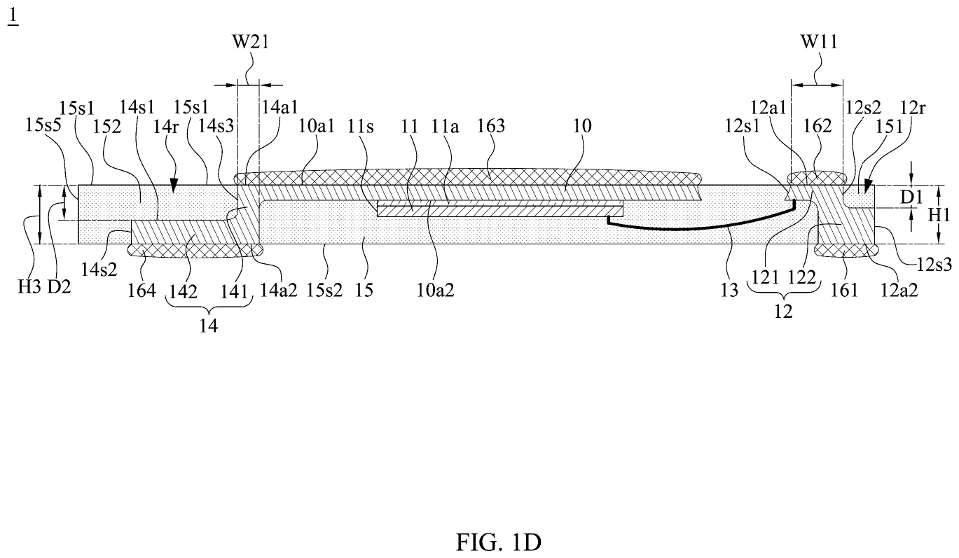

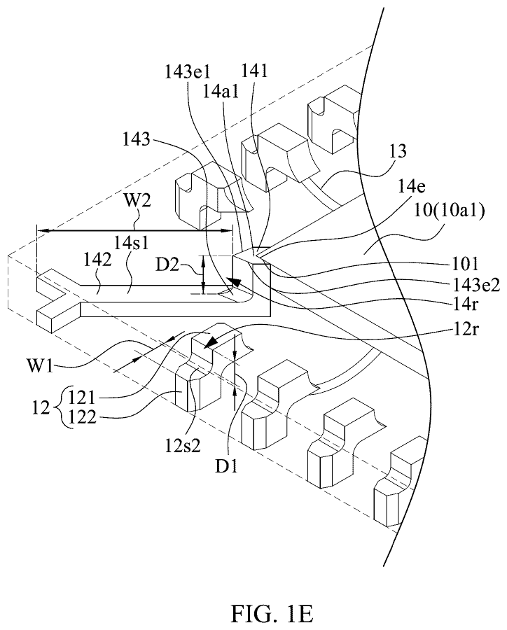

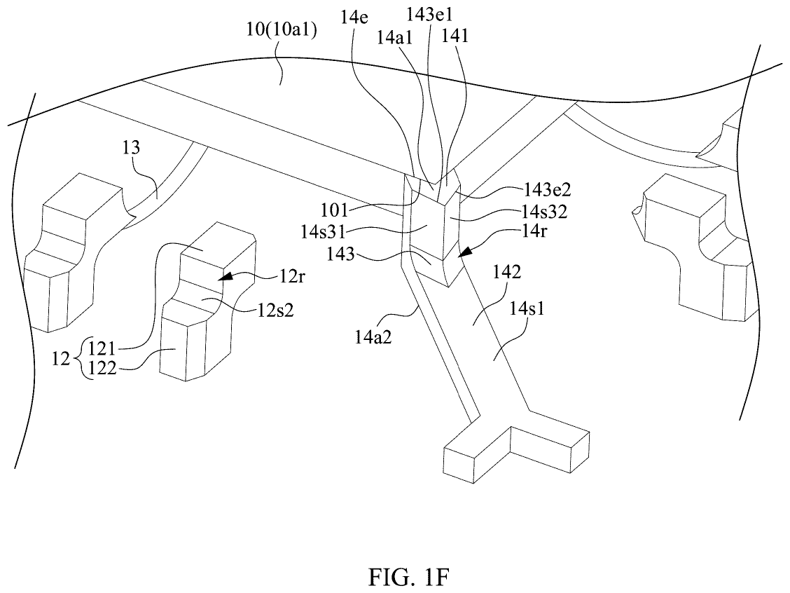

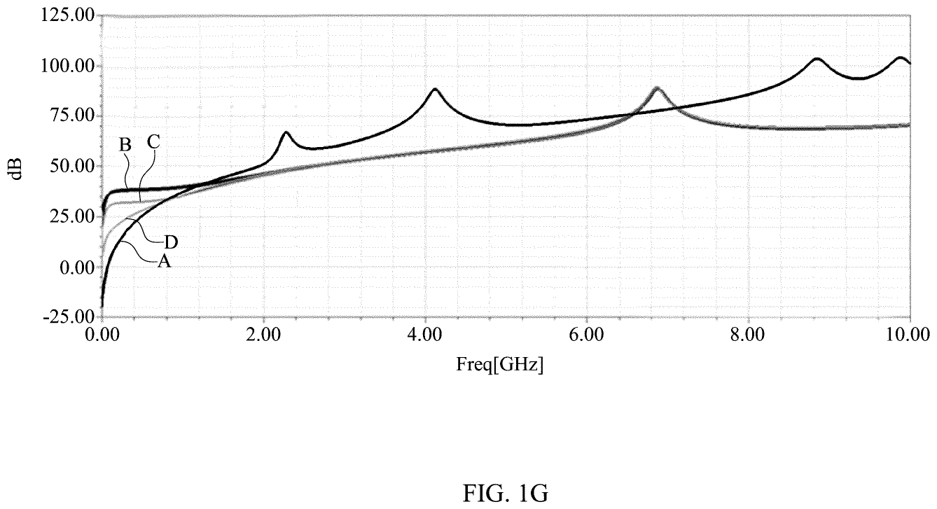

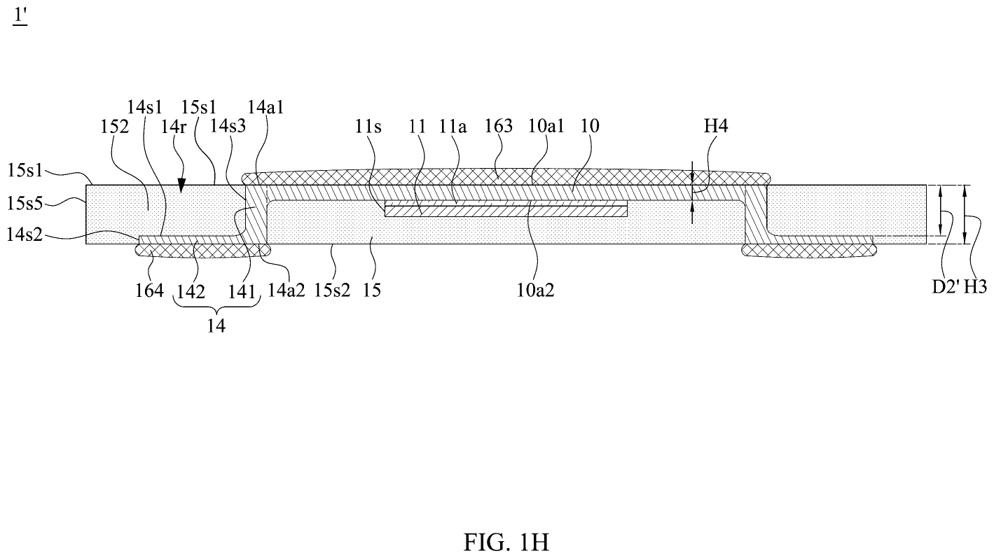

FIG. 1 illustrates a bottom view of an electronic device 1 according to some embodiments of the present disclosure. The electronic device 1 may include a carrier (or a conductive base, a flag, a lead frame) 10, an electronic component 11, one or more leads 12, one or more wirings 13, one or more tie bars (or one or more connecting elements) 14, and an encapsulant 15. The carrier 10, the leads 12, and the tie bars 14 may be collectively referred as a conductive structure.

The carrier 10 may support the electronic component 11. The carrier 10 may be separated from the leads 12. The carrier 10 may be connected to the tie bar 14. The carrier 10 may be covered or encapsulated by the encapsulant 15. The carrier 10 may include metal or a metal alloy such as copper (Cu), gold (Au), aluminum (Al), or the alloy thereof.

The electronic component 11 may be disposed on a surface of the carrier 10. The electronic component 11 may be electrically connected to a portion of the leads through the wirings 13. In some embodiments, the electronic component 11 is configured to electrically connect to an external substrate, such as a printed circuit board (PCB) (not shown), through the leads 12. The electronic component 11 may be covered or encapsulated by the encapsulant 15. The electronic component 11 may include a semiconductor die. In some embodiments, the electronic component 11 may include one or more processing elements and one or more memory elements electrically connected to the processing elements. The processing element(s) and the memory element(s) may be divided from or originate in a monolithic processing unit (e.g., a CPU, a MPU, a GPU, a MCU, an ASIC, or the like). In some embodiments, the processing element may be a CPU chiplet, a MCU chiplet, a GPU chiplet, an ASIC chiplet, or the like.

The leads 12 may be spaced apart from the carrier 10. The leads 12 may surround the electronic component 11 or the carrier 10. The leads 12 may be disposed at four sides of the periphery of the electronic device 1. The lead 12 may be disposed at a side of the electronic component 11. The leads 12 may be arranged as an array. The leads 12 may be spaced apart from each other. The leads may have a width larger than a spacing therebetween. A portion of the leads 12 may be connected to the wirings 13. The wirings 13 may include bond wirings. The leads 12 may be spaced apart from the tie bars 14 by the encapsulant 15. The leads 12 may be covered or encapsulated by the encapsulant 15. The leads 12 may have a portion (or a horizontal portion, extension portion) 121 covered by the encapsulant 15 and a portion (or a vertical portion) 122 exposed from the encapsulant 15 in the top view. The portion 121 is connected to the portion 122. The portion 121 may have a surface area sufficient for attaching to the wiring 13.

A portion of the wirings 13 may be electrically connected to the carrier 10 and a portion of the leads 12 to apply a voltage to the carrier 10 from the leads 12. The voltage may be a grounding or a reference voltage.

The tie bars 14 may be disposed at four corners of the electronic device 1. One of the tie bars 14 may be disposed between two leads 12, which are disposed at different sides of the periphery of the electronic device 1. The tie bar 14 may has a surface (or an upper surface) 14a1 between the adjacent two leads 12. Such two leads 12 may have a substantially triangular shape, different from other leads. The tie bars 14 may be configured to support the carrier 10 and the electronic component 11 attached to the carrier 10 before the encapsulant 15 is formed. The tie bars 14 may have a portion 141 (or a connection portion) covered by the encapsulant 15 and a portion 142 (or an elongated portion) exposed from the encapsulant 15 in the top view. The tie bars 14 may be connected to the electronic component 11 through the carrier 10. The portions 141 of the tie bars 14 may be connected to a corner or an edge of the carrier 10. The tie bars 14 may directly contact the carrier 10.

The portion 142 of the tie bar 14 may have an end 14e with a forked shape. The end 14e may have a latch structure (indicated as the numeral 14e for brevity) configured to lock the tie bar 14 and the encapsulant 15. The portion 122 of the lead 12 may have an end 12e. The end 14e of the portion 142 of the tie bar 14 may be closer to the carrier 10 than the end 12e of the portion 122 of the lead 12.

The leads 12 or the tie bars 14 may include metal or a metal alloy such as copper (Cu), gold (Au), aluminum (Al), or the alloy thereof. In some embodiments, the carrier 10, the leads 12, and the tie bars 14 may be integrally formed. In particular, the leads 12 and the tie bars 14 may be formed by partial etching the carrier 10 into a predetermined thickness. The partial etching may include half-etching.

The encapsulant 15 may include an epoxy resin including fillers, a molding compound (e.g., an epoxy molding compound or other molding compound), polyimide, a phenolic compound or material, a material including silicone dispersed therein, or a combination thereof.

FIG. 1A illustrates a top view of the electronic device 1 according to some embodiments of the present disclosure. The top view indicates an opposite angle of view to the bottom view. The top view and the bottom view may be interchangeable. As shown in FIG. 1A, the portion 121 of lead 12 may be exposed from the encapsulant 15 in the top view and the portion 141 of the tie bar 14 may be exposed from the encapsulant 15 in the top view. The tie bar 14 may include a latch structure 143 between the portions 141 and 142. The carrier 10 may have a surface (or an upper surface, a top surface) 10a1, opposite to a surface 10a2 that supports the electronic component 11, exposed from the encapsulant 15. A portion of the carrier 10 may be exposed by the encapsulant 15.

FIG. 1B illustrates a cross-sectional view of an electronic device (or the electronic device 1) according to some embodiments of the present disclosure. FIG. 1B may be a cross section along the line 1B-1B′ of FIG. 1A.

As shown in FIG. 1B, the electronic component 11 may have a lateral surface 11s facing the leads 12. The electronic component 11 may be disposed under the carrier 10. The electronic component 11 may be attached to the surface 10a2 of the carrier 10 through an adhesive layer 11a. The adhesive layer 11a may be in contact with the surface 10a2 of the carrier 10 or an electrode (not shown) of the electronic component 11. The adhesive layer 11a may be beneficial to the thermal dissipation from the electronic component 11 to the carrier 10. Furthermore, the adhesive layer 11a may include an electrically conductive material such as silver (Ag), nickel (Ni), copper (Cu), graphite or another suitable alternative. The electronic component 11 may be electrically connected to the carrier 10 through the adhesive layer 11a with its electrically conductive nature. In some embodiments, the electronic component 11 is configured to electrically connect to an external substrate, such as a printed circuit board (PCB) (not shown), through the carrier 10.

The carrier 10 and the leads 12 may define a bowl shape structure for accommodating the electronic component 11. The portion 121 of the lead 12 may be adjacent to the lateral surface 11s of the electronic component 11. The lead 12 (or the portion 121) may have a curved surface 12s1 facing the carrier 10. The carrier 10 may have a curved surface 10s facing the curved surface 12s1 of the portion 121 of the lead 12. The curved surface 12s1 and the curved surface 10s may define a recess (or an opening) 10r between the carrier 10 and the portion 121 of the lead 12. The encapsulant 15 may have a portion 150 disposed in the recess 10r.

The curved surface 10s and the curved surface 12s1 may have different curvatures. In some embodiments, the curved surface 12s1 of the lead 12 has a first curvature and the curved surface 10s of the carrier 10 has a second curvature. The first curvature and the second curvature have substantially a same magnitude but opposite signs.

The lead 12 may extend through the encapsulant 15. The lead 12 may have a height H1 higher than a height H2 of the electronic component 11. A height of the portion 122 of the lead 12 may be higher than a height (or thickness) H4 of the carrier 10. A depth D1 of the recess 12r may be larger than the height H4 of the carrier 10. The lead 12 (or the portion 121) may have a surface (or an upper surface, a top surface) 12a1 exposed from the encapsulant 15. The lead 12 (or the portion 122) may have a surface 12a2 opposite to the surface 12a1 and exposed from the encapsulant 15. The encapsulant 15 may have a surface (or a top surface) 15s1 and a surface 15s2 opposite to the surface 15s1. The surface 12a1 of the lead 12 and the surface 15s1 of the encapsulant 15 may be substantially coplanar. The surface 12a1 of the lead 12 may be substantially aligned with the surface 15s1 of the encapsulant 15. The surface 10a1 of the carrier 10 may be substantially aligned with the surface 12a1 of the lead 12. The surface 12a2 of the lead 12 and the surface 15s2 of the encapsulant 15 may be substantially coplanar.

The lead 12 may have a curved surface (or an upper surface) 12s2 connected to the surface 12a1. The curved surface 12s2 may be opposite to the curved surface 12s1. The curved surface 12s2 may define a recess 12r. The recess 12r may be recessed from the surface 12a1. The encapsulant 15 may have a portion 151 disposed in the recess 12r. In other words, the recess 12r may be covered by the portion 151. The portion 151 of the encapsulant 15 may be separated from the portion 150 of the encapsulant 15 in the cross section.

In some embodiments, the lead 12 may have an upper surface having a portion (i.e., the curved surface 12s2) covered by the encapsulant 15 and a portion (i.e., the surface 12a1) exposed from the encapsulant 15. The portion (or the curved surface) 12s2 of the upper surface of the lead 12 and the portion (or the surface) 12a1 of the upper surface of the lead 12 may be non-coplanar.

The lead 12 (or the portion 122) may have a lateral surface 12s3 connected between the surface 12a2 and the curved surface 12s2. The curved surface 12s2 may extend between the surface 12a2 and the lateral surface 12s3. The lateral surface 12s3 may be exposed from the encapsulant 15 (or the portion 151). Given that the curved surface 12s2 and the lateral surface 12s3 may be formed in different processes, the curved surface 12s2 and the lateral surface 12s3 may have different surface roughnesses. For example, the curved surface 12s2 may be formed by an etching process and the lateral surface 12s3 may be formed by a singulation process. In some embodiments, the portion 151 may have a lateral surface 15s3. The portion 122 of the lead 12 may be exposed from the surface 15s2 and the lateral surface 15s3 of the encapsulant 15. The lateral surface 12s3 of the lead 12 and the lateral surface 15s3 of the encapsulant 15 may be substantially coplanar. The lateral surface 12s3 of the lead 12 may be substantially aligned with the lateral surface 15s3 of the encapsulant 15.

In some cases, a Quad Flat No-Lead (QFN) package may include an additional metal layer and additional wirings connecting the additional metal layer to a lead frame of the QFN package to provide electromagnetic shielding. However, the effect of the electromagnetic shielding is not satisfactory, such that a device in the QFN package may be severely influenced by unwanted electromagnetic waves from the environment. In the present disclosure, the bowl shape structure as defined by the carrier 10 and one or more leads 12 of the electronic device 1 functions as a Faraday cage for shielding the electronic device 11 from the environment. Therefore, the carrier 10 and one or more leads 12 may be collectively configured as an electromagnetic shielding structure for the electronic component 11. The carrier 10 and the lead 12 are configured to block an electromagnetic wave between the electronic component 11 and an external of the electronic device 11. The number and size (or width) of the leads 12 are greater than that of the wirings, which improves the shielding effect in the periphery of the electronic device 1. Furthermore, without forming an additional metal layer or wirings as required by a QFN package, the size (or the height) of the electronic device 1 can be relatively small.

FIG. 1B-1 illustrates another cross-sectional view of an electronic device according to some embodiments of the present disclosure. FIG. 1B-1 may be a cross section along the line 1B-1B′ of FIG. 1A. FIG. 1B-1 is similar to FIG. 1B, and some detailed descriptions may refer to corresponding preceding paragraphs and are not repeated hereinafter for conciseness, with differences therebetween as follows.

As shown in FIG. 1B-1, the carrier 10 may have a surface 10s′ facing the portion 121 of the lead 12. The lead 12 may have a surface 12s1′ facing the surface 10s′ of the carrier 10. The surface 10s′ may be a substantially flat surface. The surface 12s1′ may be a substantially flat surface. The surface 12s1′ and the surface 10s′ may define a recess (or an opening) 10r′ between the carrier 10 and the portion 121 of the lead 12. The encapsulant 15 may have a portion 150 disposed in the recess 10r′.

FIG. 1C illustrates a cross-sectional view of an electronic device (e.g., the electronic device 1) according to some embodiments of the present disclosure. FIG. 1C may be a cross section along the line 1C-1C′ of FIG. 1A.

The tie bar 14 may extend through the encapsulant 15. The tie bar 14 may have a height H3 substantially the same as the height H1 of the lead 12 as shown in FIG. 1B. A height of the portion 142 of the tie bar 14 may be higher than the height H4 of the carrier 10. A depth D2 of the recess 14r may be larger than the height H3 of the carrier 10. The tie bar 14 (or the portion 141) may have a surface (or an upper surface) 14a1 exposed from the encapsulant 15. The tie bar 14 (or the portion 142) may have a surface 14a2 opposite to the surface 14a1 and exposed from the encapsulant 15. The surface 14a1 of the tie bar 14 and the surface 12a1 of the lead 12 may be coplanar. The surface 14a2 of the tie bar 14 and the surface 12a2 of the lead 12 may be substantially coplanar. The surface 14a2 of the tie bar 14 and the surface 15s2 of the encapsulant 15 may be substantially coplanar.

The portion 142 may be recessed from the surface 14a1 of the tie bar 14. The tie bar 14 (or the portion 142) may have a surface 14s1 substantially parallel with the surface 14a1 and a surface (or a side) 14s3 connected between the surface 14a1 and the surface 14s1. The surface 14s1 may be a flat surface. The surface 14s1 may be a curved surface. The surface 14s3 may be a curved surface. The surface 14s1 and surface 14s3 may define a recess 14r. The recess 14r may be recessed from the surface 14a1. The surface 14s1 of the tie bar 14 and the curved surface 12s2 of the lead 12 may have substantially the same or similar surface roughnesses because they may be formed in the same process, e.g., an etching process. The encapsulant 15 may have a portion 152 disposed in the recess 14r. In other words, the recess 14r may be covered by the portion 152. The surfaces 14s1 and 14s3 may be covered by the encapsulant 15. The portion 152 of the encapsulant 15 may have a surface 15s4 substantially coplanar with the surface 10a1 of the carrier 10 or the surface 14a1 of the tie bar 14.

In some embodiments, the tie bar 14 may have an upper surface having a portion (i.e., the surface 14s1) covered by the encapsulant 15 and a portion (i.e., the surface 14a1) exposed from the encapsulant 15. The portion (or the surface) 14s1 and/or 14s3 of the upper surface of the tie bar 14 and the portion (or the surface) 14a1 of the upper surface of the tie bar 14 may be non-coplanar. The portion (or the surface) 14s1 and/or 14s3 of the upper surface of the tie bar 14 may be larger than the portion (or the curved surface) 12s1 of the upper surface of the lead 12.

The tie bar 14 (or the portion 142) may have a lateral surface 14s2 connected between the surface 14a2 and the surface 14s1. The lateral surface 14s2 may be covered by the encapsulant 15 (or the portion 152). In some embodiments, the portion 152 may have a lateral surface 15s5 connected to the surface 15s4 of the portion 152. The lateral surface 15s5 may be substantially parallel with the lateral surface 14s2.

The tie bars 14 may be disposed at the corners of the electronic device 1. The tie bars 14 may be part of the electromagnetic shielding structure for the electronic component 11 and can improve the shielding effect of the electronic device 1. The tie bar 14 is configured to block the electromagnetic wave between the electronic component 11 and the external of the electronic device 11.

The electronic device 1 may further include a conductive element 161 disposed over the surface 12a2 of the lead 12, a conductive element 162 disposed over the surface 12a1 of the lead 12, and a conductive element 163 disposed over the surface 10a1 of the carrier 10. The conductive elements 161, 162, and 163 may each include a solder bump. The conductive elements 161 and 162 may each include a ball grid array. The conductive element 163 may include a land grid array. In some embodiments, no conductive element may be disposed over the surface 12a1 of the lead 12 and the surface 10a1 of the carrier 10.

Even though the surfaces 12a1, 12a2, and 10a1 may be covered by the conductive elements, it is legitimate to refer to them as exposed surfaces that are exposed from the encapsulant 15. The conductive elements 161, 162, and 163 may protect the exposed surface 12a1, 12a2, and 10a1 to prevent the oxidation thereof.

The electronic device 1 may further include a conductive element 164 disposed over the surface 14a2 of the tie bar 14. The conductive element 161 may be disposed over the surface 14a1 of the tie bar 14. The conductive element 164 may include a solder bump. The conductive element 164 may each include a ball grid array.

Even though the surfaces 14a1 and 14a2 may be covered by the conductive elements, it is legitimate to refer to them as exposed surfaces that are exposed from the encapsulant 15. The conductive elements 161 and 164 may protect the exposed surface 14a1 and 14a2 to prevent the oxidation thereof.

FIG. 1D illustrates a cross-sectional view of an electronic device (e.g., the electronic device 1) according to some embodiments of the present disclosure. FIG. 1D may be a cross section along the line 1D-1D′ of FIG. 1A.

As shown in FIG. 1D, an area of the upper surface 14a1 of the tie bar 14 may be less than an area of the upper surface 12a1 of the lead 12. In particular, a width W21 of the upper surface 14a1 of the tie bar 14 may be less than a width W11 of the upper surface 12a1 of the lead 12 in a cross-sectional view. The area (or width) of the upper surface 12a1 of the lead 12 is designed to be large sufficient for attaching the wirings 13. The tie bar 14 is for supporting the carrier 10 and for defining the portion 152 of the encapsulant 15 in the recess 14r. Thus, the area (or width) of the upper surface 14a1 of the tie bar 14 is designed to be larger than that of the upper surface 12a1 of the lead 12. As such, the volume of the portion 152 of the encapsulant 15 disposed on the upper surface 14a1 (or in the recess 14r) may be larger to improve the shielding effect. For example, the S11 parameter can be increased and/or the S21 parameter can be decreased.

FIG. 1E illustrates a perspective view of an electronic device (e.g., the electronic device 1) according to some embodiments of the present disclosure. The perspective view of FIG. 1E may be a portion of the top of the electronic device 1. The encapsulant 15 is presented as being transparent for the purpose of the explanation. The encapsulant 15 may be opaque.

The recess 12r of the lead 12 may have a depth D1 in a direction perpendicular to the surface 10a1 of the carrier 10 (also shown in FIG. 1B). The recess 14r of the tie bar 14 may have a depth D2 in a direction perpendicular to the surface 10a1 of the carrier 10 (also shown in FIG. 1C). The depth D1 of the recess 12r of the lead 12 may be shorter than the depth D2 of the recess 14r of the tie bar 14. The recess 12r of the lead 12 may have a width W1 defined by a portion of the curved surface 12s2 at the portion 121 and the lateral surface 15s3 of the encapsulant 15. The curved surface 12s2 may have the width W1. The recess 14r of the tie bar 14 may have a width W2 defined by a portion of the surface 14s1 of the portion 141 and the lateral surface 15s3 of the encapsulant 15. The surface 14s1 may have the width W2. The width W2 of the recess 14r of the tie bar 14 may be greater than the width W1 of the recess 12r of the lead 12.

The thickness and the width of the portion 151 of the encapsulant 15 may be respectively indicated as the depth D1 and the width D1 of the recess 12r of the lead 12. The carrier 10, one or more leads 12, and the encapsulant 15 (or the portion 151) may be collectively configured as an electromagnetic shielding structure for the electronic component 11. The encapsulant 15 has a material with a dielectric constant of around 4. The portion 151 of the encapsulant 15 covers the curved surface 12s2 of the lead 12. The portion 151 of the encapsulant 15 can increase the reflection of the electromagnetic waves, thereby improving the shielding effect. The S11 parameter can be increased and/or the S21 parameter can be decreased.

Furthermore, the larger the width of the portion 151 is, the higher the reflection of the electromagnetic waves will be. However, there is a compromise between the width of the portion 151 (e.g., the width of the recess 12r) and the landing area of the portion 121 for the wiring 13. A size design can fulfil both of the requirements. In addition, the encapsulant 15 may have a relatively high permeability to improve the reflection of electromagnetic waves.

The thickness and the width of the portion 152 of the encapsulant 15 may be respectively indicated as the depth D2 and the width D2 of the recess 14r of the tie bar 14. The carrier 10, one or more leads 12, and the encapsulant 15 (or the portion 152) may be collectively configured as an electromagnetic shielding structure for the electronic component 11. The encapsulant 15 has a material with a dielectric constant of around 4. The portion 152 of the encapsulant 15 covers the surface 14s1 of the tie bar 14. The portion 152 of the encapsulant 15 can increase the reflection of the electromagnetic waves, thereby improving the shielding effect. The S11 parameter can be increased and/or the S21 parameter can be decreased.

Furthermore, the larger the width of the portion 152 is, the higher the reflection of the electromagnetic waves will be. Different from the portion 151, there is no limitation on the width of the portion 152 as long as the tie bar 14 can connect to the carrier 10.

The latch structure 143 of the tie bar (or the connecting element) 14 may extend from the surface 14a1 toward the surface 14s1. The latch structure 14e may match a corner 101 of the carrier 10. The latch structure 143 and the latch structure 14e may be in contact with the encapsulant 15. The latch structure 143 and/or the latch structure 14e may be configured to lock the tie bar 14 and the encapsulant 15. The surface 14a2 (or a bottom surface) of the tie bar 14 is opposite to the upper surface 14a1 of the tie bar 14 and exposed by the encapsulant 15. An area of the surface 14a2 may be greater than the area of the surface 14a1.

FIG. 1F illustrates a perspective view of an electronic device (e.g., the electronic device 1) according to some embodiments of the present disclosure. The perspective view of FIG. 1F may be a portion of the top of the electronic device 1. The encapsulant 15 is presented as being transparent for the purpose of the explanation. The encapsulant 15 may be opaque.

The tie bar 14 has a first edge 143e1 and a second edge 143e2. The first edge 143e1 and the second edge 143e2 overlap the surface 14a2 of the tie bar 14 in a direction perpendicular to the surface 14a2. The surface 14s1 of the tie bar 14 may be covered by the encapsulant 15. The tie bar 14 may have a first side 14s31 extending from the first edge 143e1 to the surface 14s1 of the tie bar 14 and a second side 14s32 extending from the second edge 143e2 to the surface 14s1 of the tie bar 14. The first side 14s31 is non-parallel with the second side 14s32.

FIG. 1G illustrates a plot of the intensity of electromagnetic waves versus frequency according to some embodiments of the present disclosure. FIG. 1G shows four conditions A, B, C, and D. The condition A indicates the distribution of the intensity of electromagnetic waves versus frequency after interacting with a conventional QFN package (having an additional metal layer). The condition B indicates the distribution of the intensity of electromagnetic waves versus frequency after interacting with the electronic device 1.

As shown in FIG. 1G, in the relatively high frequency region (e.g., over 8 GHZ), the intensity of electromagnetics wave of the condition B is smaller than that of the condition A. The intensity difference may be in a range from about 15 to about 40 dB. Furthermore, in the relatively medium frequency region (e.g., between 2 and 6 GHz), the intensity of electromagnetic waves of the condition B is smaller than that of the condition A. This means that the electromagnetic shielding structure of the electronic device 1 blocks more electromagnetic waves than the conventional QFN package in these frequency regions.

On the other hand, in the relatively low frequency region (e.g., less than 1 GHz), the intensity of electromagnetic waves of the condition B is larger than that of the condition A. The shielding effect of the electronic device 1 in the relatively low frequency region can be improved by covering the exposed surfaces of the electronic device 1. For example, the surface 10a1 of the carrier 10 can be covered by the encapsulant 15. The condition C indicates the distribution of the intensity of electromagnetic waves versus frequency after interacting with the electronic device 1 with the covered surface 10a1 of the carrier 10. In the relatively low frequency region (e.g., less than 1 GHZ), the intensity of electromagnetic waves of the condition C is smaller than that of the condition B. To further improve the shielding effect, the electronic device 1 may be completely covered by the encapsulant, except for the parts to be connected to an external system. The condition D indicates the distribution of the intensity of electromagnetic waves versus frequency after interacting with the completely covered electronic device 1. In the relatively low frequency region (e.g., less than 1 GHZ), the intensity of an electromagnetic wave of the condition D is smaller than that of the condition C.

FIG. 1H illustrates a cross-sectional view of an electronic device 1′ according to some embodiments of the present disclosure. The electronic device 1′ in FIG. 1H is similar to the electronic device 1 in FIG. 1. Therefore, some detailed descriptions may refer to corresponding preceding paragraphs and are not repeated hereinafter for conciseness, with differences therebetween as follows.

The recess 14r′ of the tie bar 14 of the electronic device 1′ may have a depth D2′ higher than the depth D2 of the recess 14r as shown in FIG. 1C. Thus, the thinner tie bar 14 may improve the warpage of the electronic device 1.

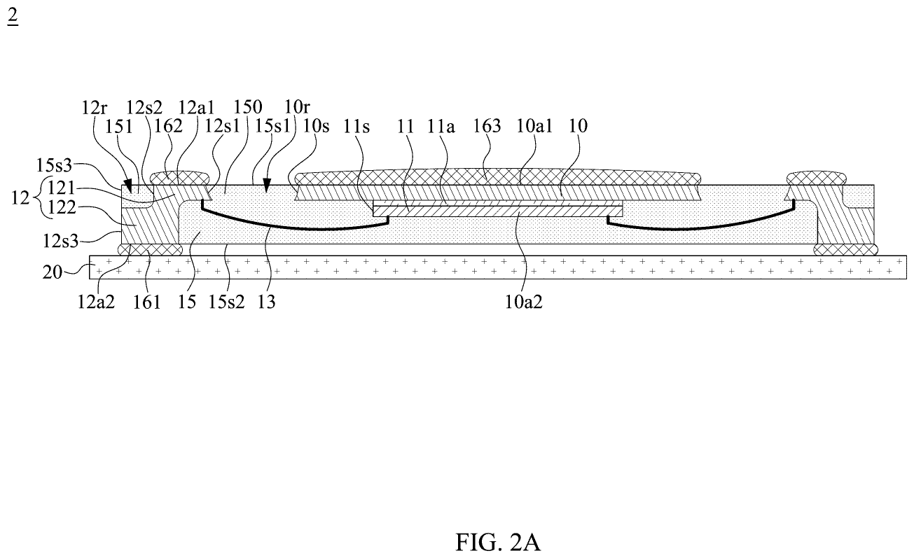

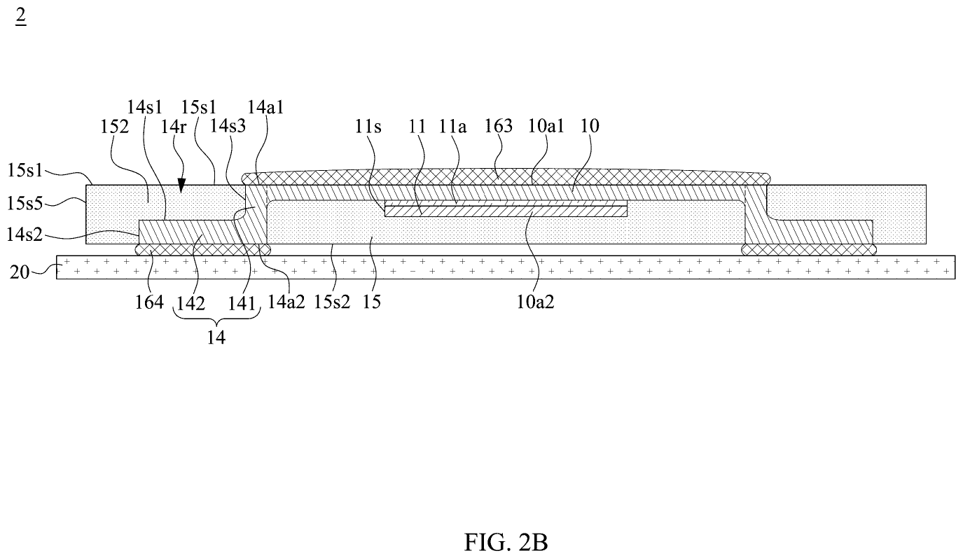

FIG. 2A illustrates a cross-sectional view of an electronic device 2 according to some embodiments of the present disclosure. FIG. 2B illustrates another cross-sectional view of an electronic device 2 according to some embodiments of the present disclosure. The electronic device 2 in FIGS. 2A and 2B is similar to the electronic device 1 in FIGS. 1B and 1C. Therefore, some detailed descriptions may refer to corresponding preceding paragraphs and are not repeated hereinafter for conciseness, with differences therebetween as follows.

The electronic device 2 may further include a circuit structure 20 attached to the surface 12a2 of the lead 12 through the conductive element 161. The electronic component 11 may be electrically connected to the circuit structure 20 through the lead (or leads) 12. The circuit structure 20 may be attached to the surface 14a2 of the tie bar 14 through the conductive element 164. The circuit structure 20 is disposed below the electronic component 11. In some embodiments, the circuit structure 20 may include an interposer. In some embodiments, the circuit structure 20 may include, for example, a printed circuit board (PCB), such as a paper-based copper foil laminate, a composite copper foil laminate, or a polymer-impregnated glass-fiber-based copper foil laminate. In some embodiments, the circuit structure 20 may include a semiconductor substrate including silicon, germanium, or other suitable materials. The circuit structure 20 may be referred to as a carrier or substrate.

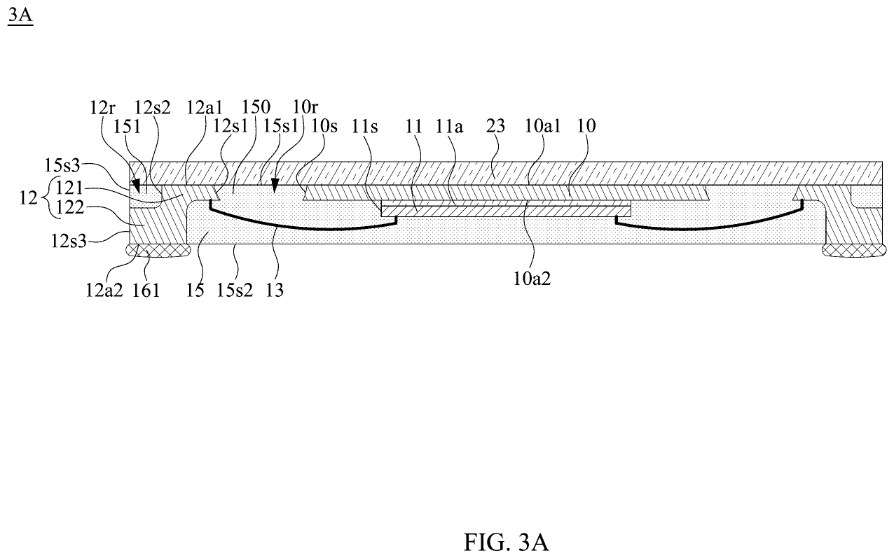

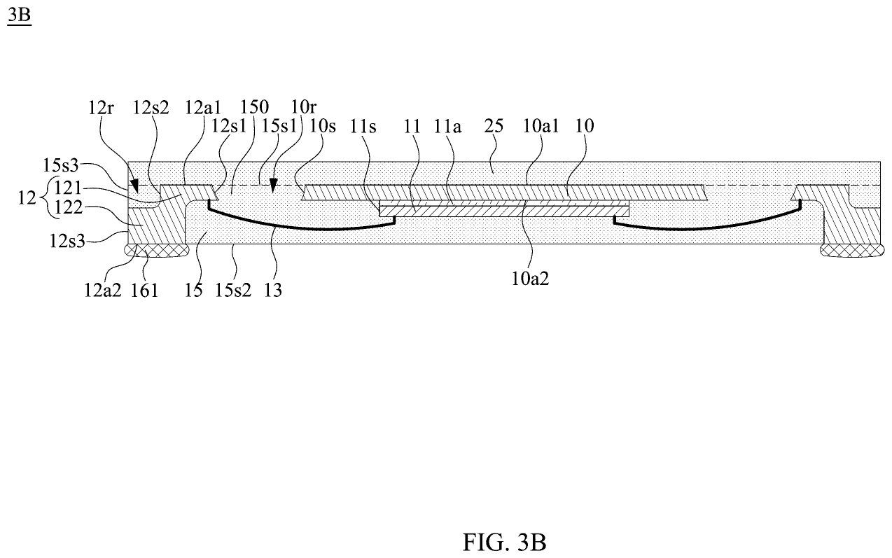

FIG. 3A illustrates a cross-sectional view of an electronic device 3A according to some embodiments of the present disclosure. The electronic device 3A in FIG. 3A is similar to the electronic device 1 in FIG. 1. Therefore, some detailed descriptions may refer to corresponding preceding paragraphs and are not repeated hereinafter for conciseness, with differences therebetween as follows.

The electronic device 3A may further include a protective layer 23 disposed over the surface 10a1 of the carrier 10 and the surface 12a1 of the lead 12. The protective layer 23 may cover the portion 121 of the lead 12 and a portion of the carrier 10. The protective layer 23 may include a solder resist. The protective layer 23 may improve the reflection of electromagnetic waves. The protective layer 23 may be part of the electromagnetic shielding structure of the electronic device 3A for the electronic component 11 and can improve the shielding effect of the electronic device 3A. The protective layer 23 is configured to block the electromagnetic wave between the electronic component 11 and the external of the electronic device 11. In some embodiments, the protective layer 23 may be formed prior to the formation of the conductive element 161.

FIG. 3B illustrates a cross-sectional view of an electronic device 3B according to some embodiments of the present disclosure. The electronic device 3B in FIG. 3B is similar to the electronic device 1 in FIG. 1. Therefore, some detailed descriptions may refer to corresponding preceding paragraphs and are not repeated hereinafter for conciseness, with differences therebetween as follows.

The electronic device 3B may further include a protective layer (or an encapsulant) 25 disposed over the surface 10a1 of the carrier 10 and the surface 12a1 of the lead 12. The protective layer 25 may include a material similar to the encapsulant 15. The protective layer 25 and the encapsulant 15 may include a substantially identical material. The protective layer 25 and the encapsulant 15 may be formed in the same process, e.g., a transfer molding process. The bottom mold of the transfer molding equipment that facing the surface 10a1 of the carrier 10 may be deeper to accommodate more encapsulant material over the surface 10a1 of the carrier 10 and the surface 12a1 of the lead 12. In some embodiments, the protective layer 25 and the encapsulant 15 may be formed in separate process steps. There may be an interface or boundary between the protective layer 25 and the encapsulant 15.

The protective layer 25 may improve the reflection of electromagnetic waves. The protective layer 25 may be part of the electromagnetic shielding structure of the electronic device 3B for the electronic component 11 and can improve the shielding effect of the electronic device 3B. The protective layer 25 is configured to block the electromagnetic wave between the electronic component 11 and the external of the electronic device 11.

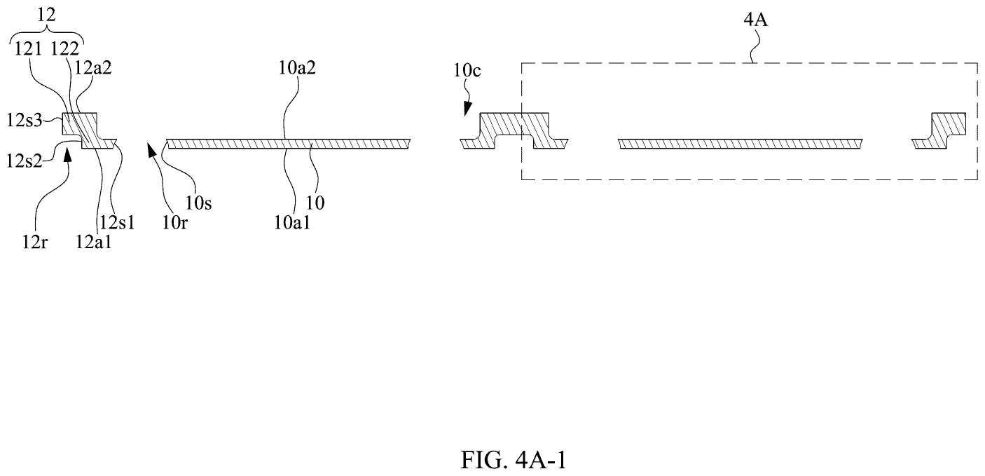

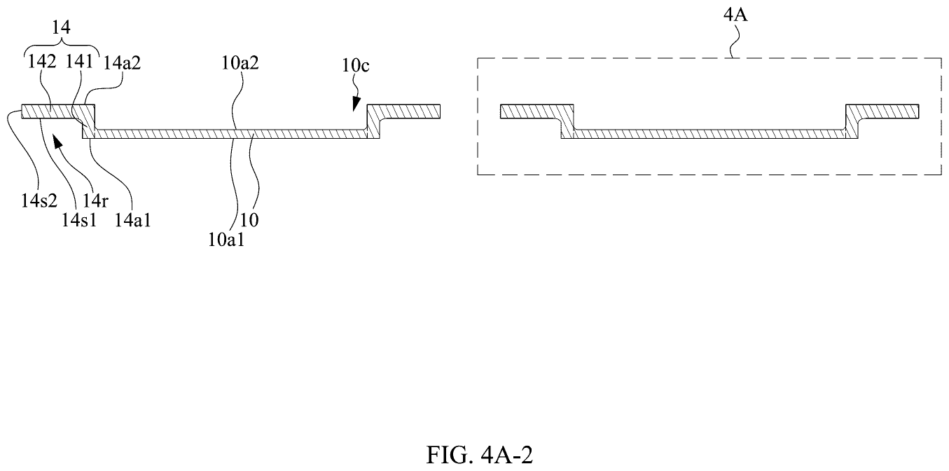

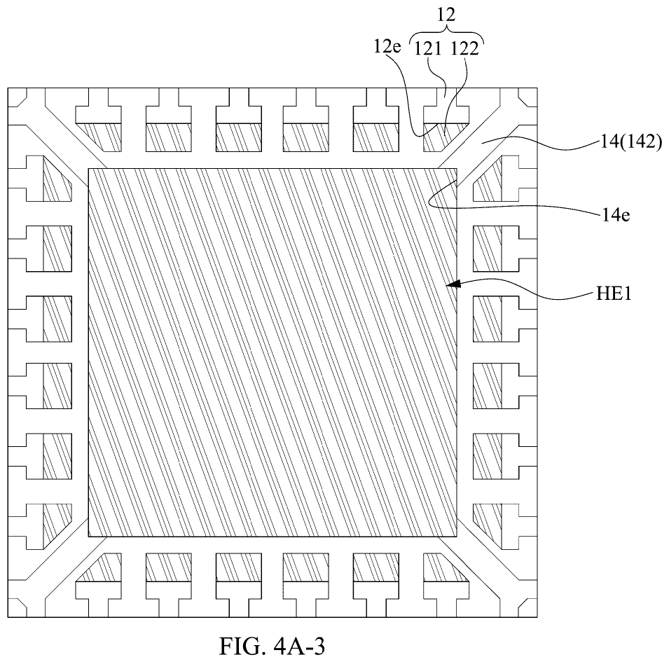

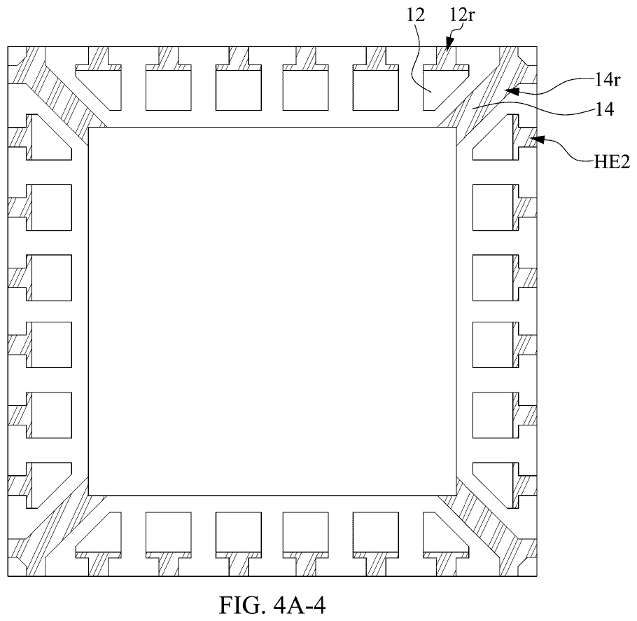

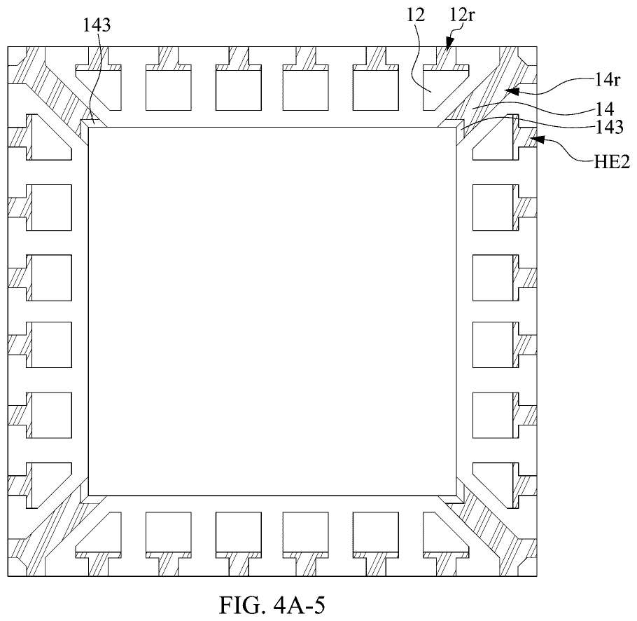

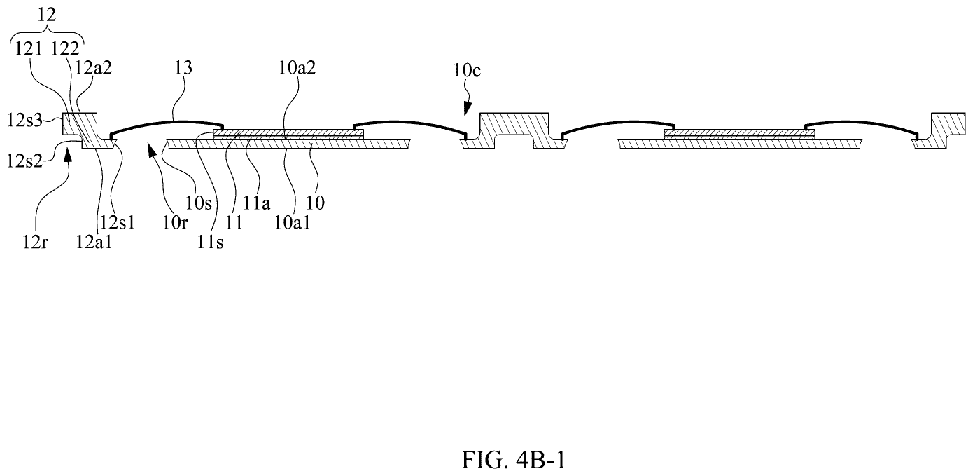

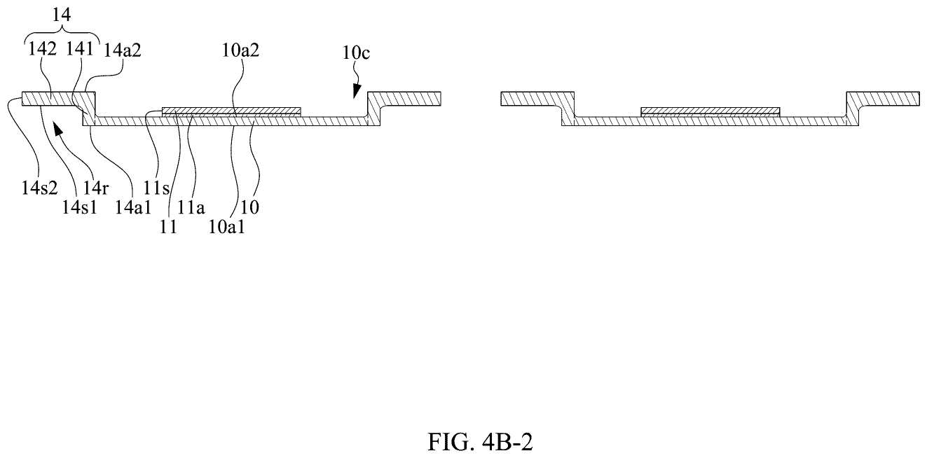

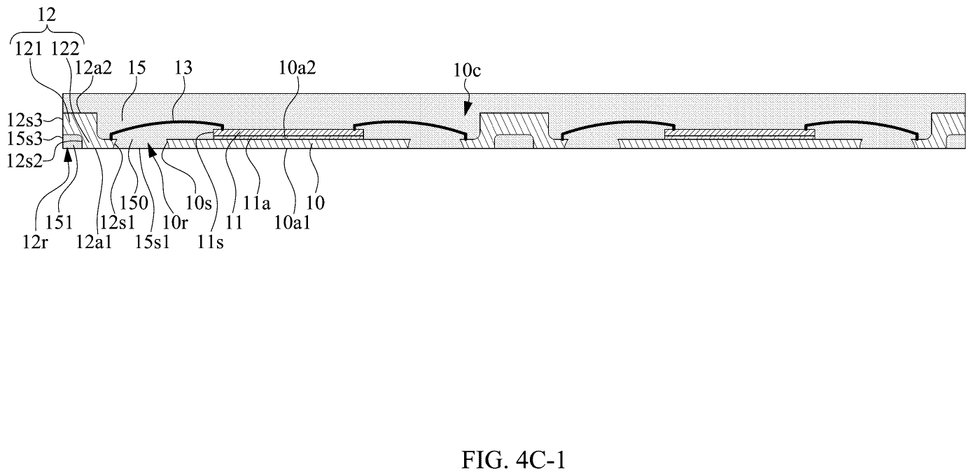

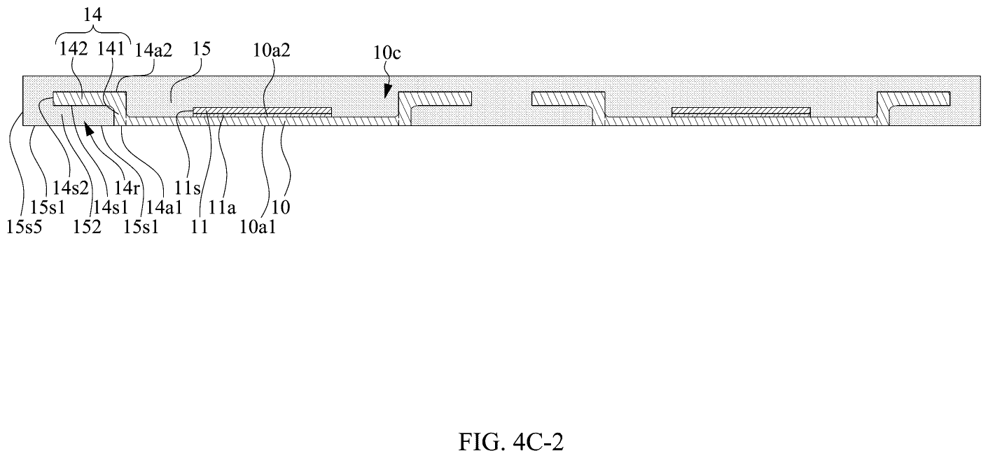

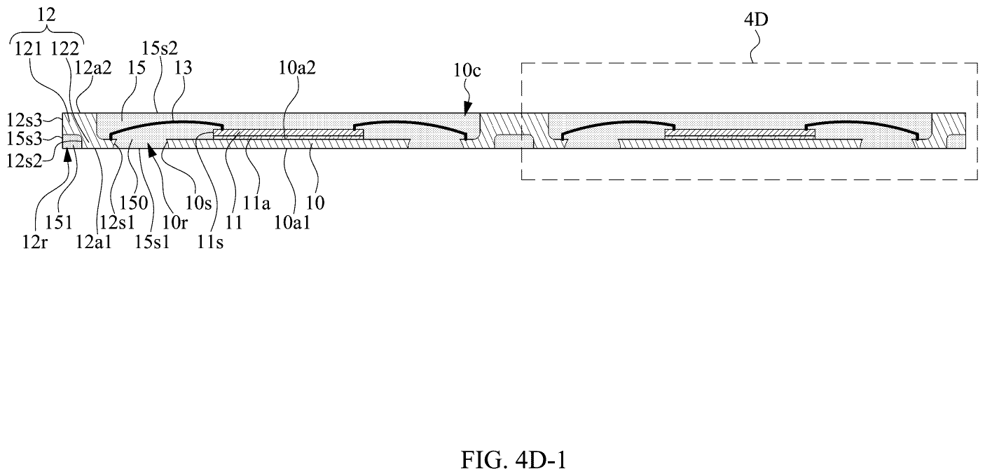

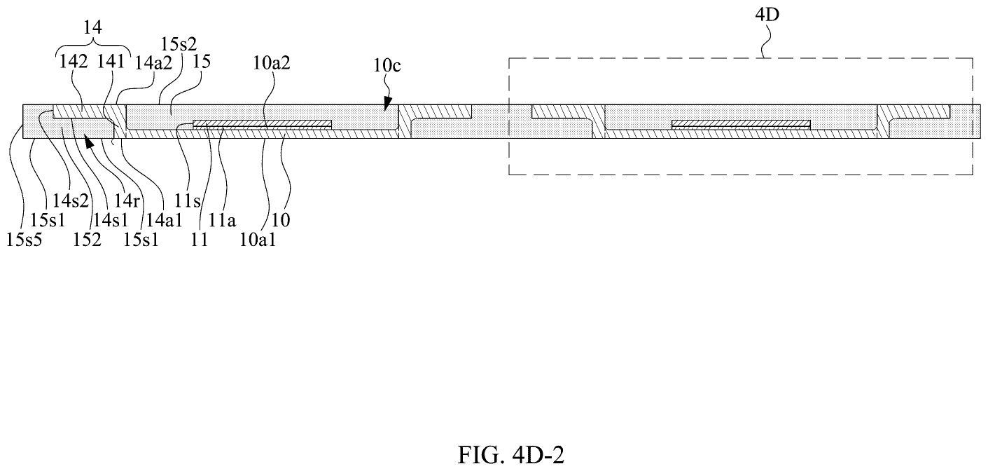

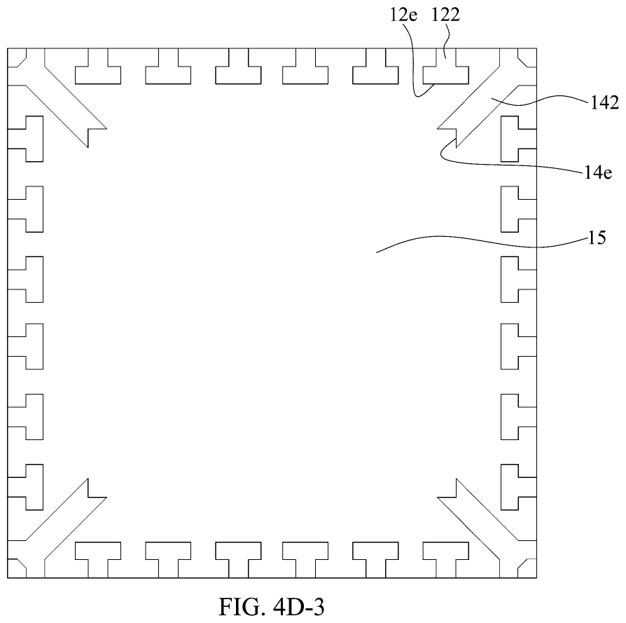

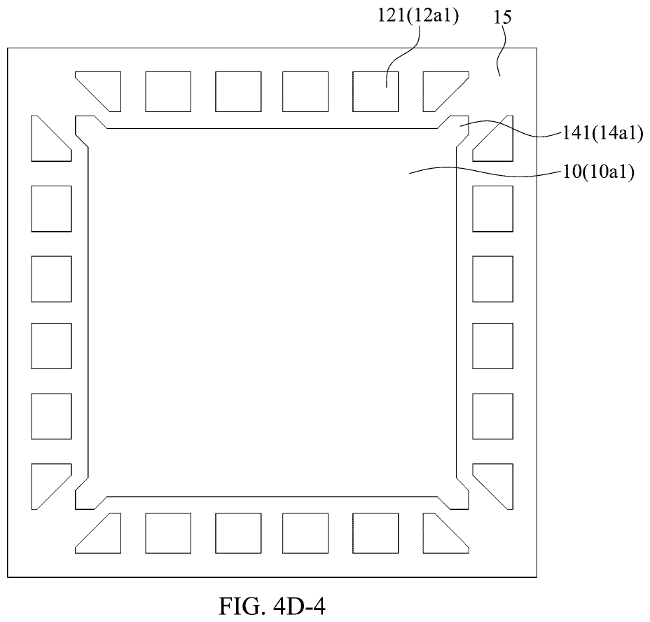

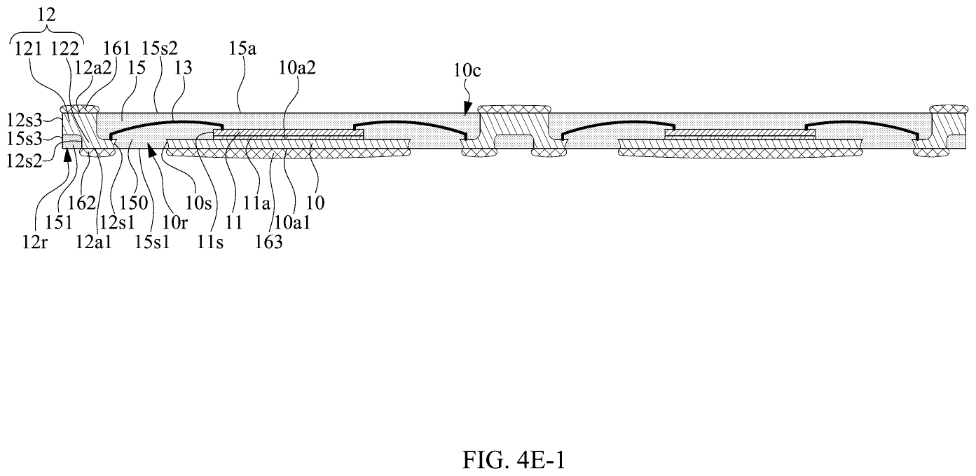

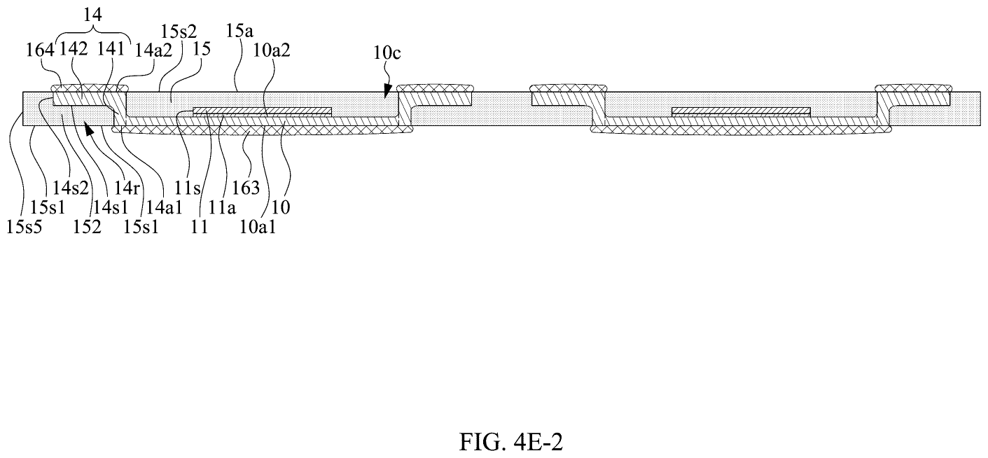

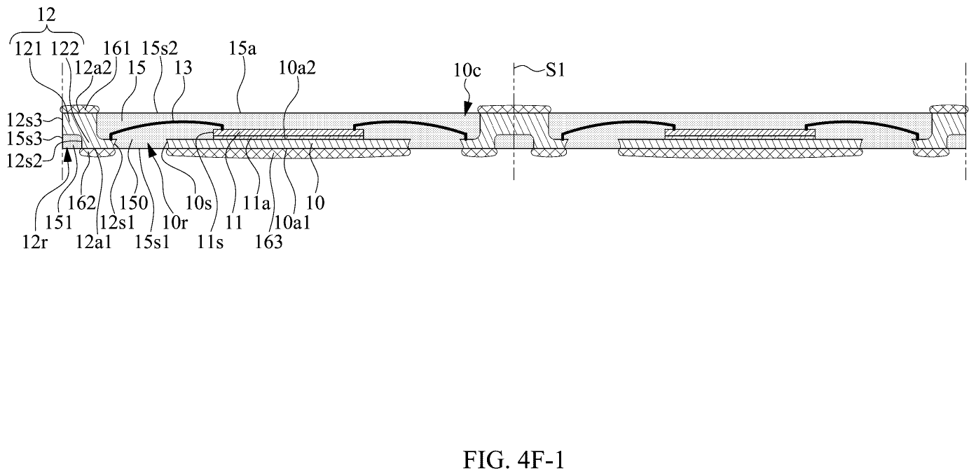

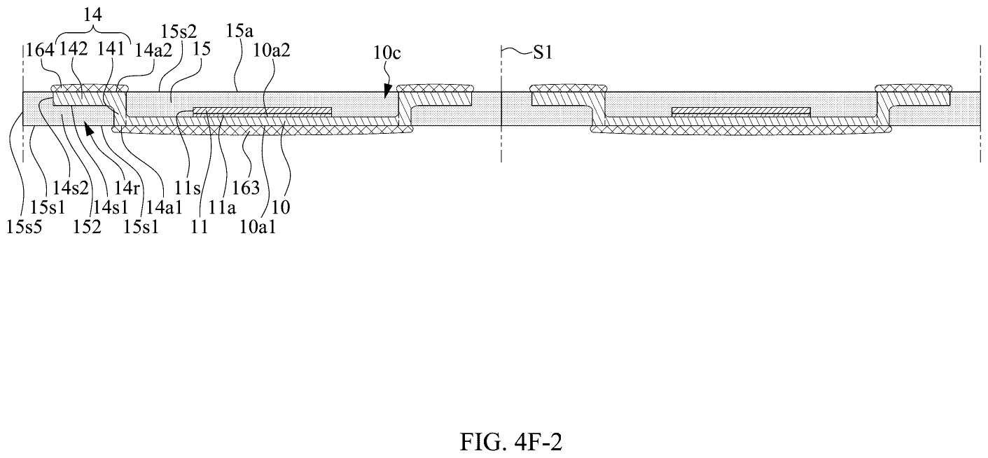

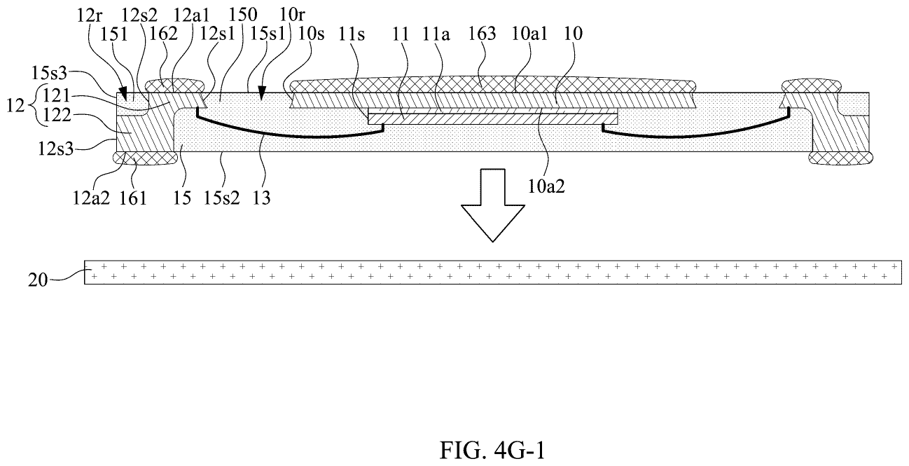

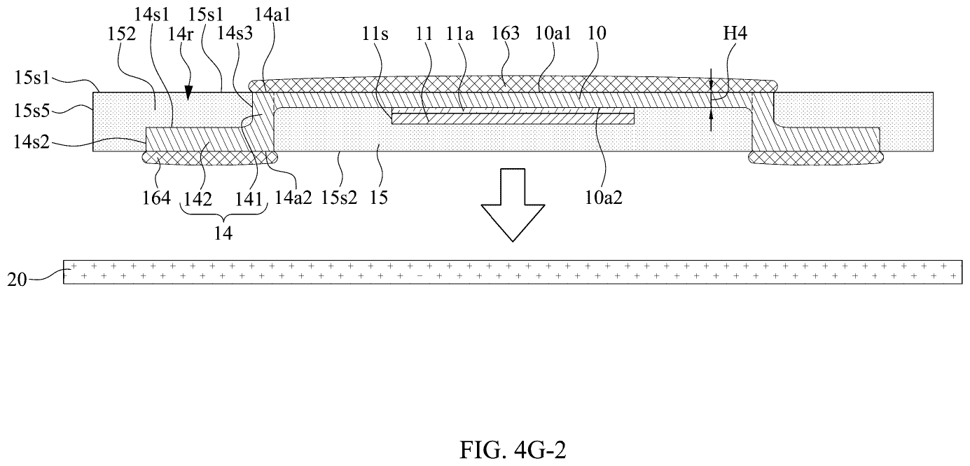

FIG. 4A-1, FIG. 4A-2, FIG. 4A-3, FIG. 4A-4, FIG. 4A-5, FIG. 4B-1, 4B-2, FIG. 4C-1, 4C-2, FIG. 4D-1, FIG. 4D-2, FIG. 4D-3, FIG. 4D-4, FIG. 4E-1, 4E-2, FIG. 4F-1, 4F-2, FIGS. 4G-1, and 4G-2 illustrate one or more stages of an example of a method for manufacturing an electronic device according to some embodiments of the present disclosure.

As shown in FIG. 4A-1 and FIG. 4A-2, a carrier 10 is provided. The carrier 10 may be partially etched from the top and the bottom to form one or more leads 12 and one or more tie bars 14. In some embodiments, the carrier 10 may be half-etched. The carrier 10, leads 12, and the tie bars 14 may define a cavity (or a bowl shape structure) 10c. The lead 12 may include a portion (or horizontal portion) 121 and a portion (or vertical portion) 122 connected to the portion 121. The portion 121 of the lead 12 and the carrier 10 may define a recess 10r therebetween. The lead 12 may define or have a recess 12r spaced apart from the recess 10r by the portion 121 of the lead 12. The tie bar 14 may include a portion (or connection portion) 141 and a portion (or elongated portion) 142 connected to the portion 141. The portion 141 of the tie bar 14 may be connected to the carrier 10. The tie bar 14 may define or have a recess 14r.

The carrier 10, the leads 12, and the tie bars 14 may each include metal or a metal alloy such as copper (Cu), gold (Au), aluminum (Al), or the alloy thereof.

FIG. 4A-3 illustrates the top view of a portion 4A of the structure of FIGS. 4A-1 and 4A-2. The lead 12 may have a T-shape structure. A region HE1 indicates the region of the partial etching from the top. The partial etching from the top defines a landing area for wirings on the portion 121 of the lead 12 and defines an end 12e of the portion 122 of the lead 12. The partial etching from the top defines an end 14e of the portion 142 of the tie bar 14. The end 14e may have a forked shape which functions as a latch structure to lock an encapsulant material.

FIG. 4A-4 illustrates the bottom view of the portion 4A of the structure of FIGS. 4A-1 and 4A-2. A region HE2 indicates the region of the partial etching from the bottom. The partial etching from the bottom defines the width and depth of the recess 12r of the lead and the recess 14r of the tie bar 14. As shown in FIG. 4A-4, the width of the recess 14r is larger than that of the recess 12r.

FIG. 4A-5 illustrates the bottom view of the portion 4A of the structure of FIGS. 4A-1 and 4A-2. A region HE2 indicates the region of the partial etching from the bottom. The partial etching from the bottom defines the width and depth of the recess 12r of the lead and the recess 14r of the tie bar 14. As shown in FIG. 4A-5, the width of the recess 14r is larger than that of the recess 12r. The partial etching from the bottom may form a latch structure 143. The details of the latch structure 143 may refer to FIG. 1E and FIG. 1F, in which the latch structure 143 may have two curved surfaces with different curvatures or two slanting surfaces with different slopes. The latch structure 143 may be configured to lock an encapsulant material in the following process.

As shown in FIGS. 4B-1 and 4B-2, an electronic component 11 is attached to a surface 10a2 of the carrier 10 through an adhesive layer 11a. The electronic component 11 is within the cavity 10c. A plurality of wirings 13 are formed to electrically connect the electronic component 11 to the leads 12. The electronic component 11 may include a semiconductor die. The wirings 13 may include a bond wiring.

As shown in FIGS. 4C-1 and 4C-2, an encapsulant 15 is formed on the carrier 10 to encapsulate the electronic component 11, the leads 12, the wirings 13, and the tie bars 14. A portion 150 of the encapsulant 15 may be formed in the recess 10r. The recesses 12r and 14r may be respectively covered by a portion 151 and a portion 152 of the encapsulant 15. The encapsulant 15 may include an epoxy resin including fillers, a molding compound (e.g., an epoxy molding compound or other molding compound), polyimide, a phenolic compound or material, a material including silicone dispersed therein, or a combination thereof.

As shown in FIGS. 4D-1 and 4D-2, the encapsulant 15 is grinded to having a surface 15s2 away from the carrier 10. The surface 15s2 of the encapsulant 15, a surface 12a2 of the lead 12 (or the portion 122), and/or a surface 14a2 of the tie bar 14 (or the portion 142) are substantially coplanar.

In the present disclosure, the bowl shape structure 10c as defined by the carrier 10 and one or more leads 12 of the electronic device 1 functions as a Faraday cage for shielding the electronic device 11 from the environment. Therefore, the carrier 10, the one or more leads 12, the tie bars 14, and/or the encapsulant 15 (e.g., in the recesses 12r and 14r) may be collectively configured as an electromagnetic shielding structure for the electronic component 11. The number and size (or width) of the leads 12 are greater than that of the wirings, which improves the shielding effect in the periphery of the electronic device 1. The encapsulant 15 that covers the recesses 12r and 14r can increase the reflection of the electromagnetic waves, and thus improve the shielding effect. The S11 parameter can be increased and/or the S21 parameter can be decreased.

Furthermore, without forming an additional metal layer or wirings as required by a QFN package, the size (or the height) of the electronic device 1 can be relatively small.

FIG. 4D-3 illustrates the top view of the structure in a dashed box 4D of FIGS. 4D-1 and 4D-2. The surface 12a2 of the portion 122 of the lead 12 may be exposed from the encapsulant 15. The surface 14a2 of the portion 142 of the tie bar 14 may be exposed from the encapsulant 15. An area of the surface 14a2 may be larger than that of the surface 12a2. The end 14e of the portion 142 of the tie bar 14 may be closer to the carrier 10 than the end 12e of the portion 122 of the lead 12.

FIG. 4D-4 illustrates the bottom view of the structure in the dashed box 4D of FIGS. 4D-1 and 4D-2. A surface 12a1 of the portion 121 of the lead 12 may be exposed from the encapsulant 15. A surface 14a1 of the portion 141 of the tie bar 14 may be exposed from the encapsulant 15. A surface 10a1 of the carrier 10 may be exposed from the encapsulant 15.

In some embodiments, a conductive element may be formed on the exposed surfaces 10a1, 12a1, 12a2, 14a1, and 14a2 to provide a connection with an external system, device, or printed circuit board. In some embodiments, some of the exposed surfaces may be covered by a protective layer (e.g., the protective layer 23 of the electronic device 3A) or an additional encapsulant (e.g., the protective layer 25 of the electronic device 3A) to improve the shielding effect.

Referring to FIGS. 4E-1 and 4E-2, a conductive element 161 is formed on the surface 12a2 of the portion 122 of the lead 12, a conductive element 162 is formed on the surface 12a1 of the portion 121 of the lead 12, a conductive element 163 is formed on the surface 10a1 of the carrier 10 and/or the surface 14a1 of the tie bar 14, and a conductive element 164 is formed on the surface 14a2 of the tie bar 14. The conductive elements 161, 162, 163, and 164 may each include a solder bump.

Referring to FIGS. 4F-1 and 4F-2, a singulation process is performed to form an electronic device 1 as shown in FIGS. 1, 1A, 1B, 1C, and 1D.

Referring to FIGS. 4G-1 and 4G-2, the electronic device 1 may be attached to a circuit structure 20 through the conductive elements 161 and 164 to form an electronic device 2 as shown in FIGS. 2A and 2B.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an electronic component having a lateral surface;
a carrier supporting the electronic component; and
a lead electrically connected to the electronic component and disposed adjacent to the lateral surface of the electronic component,
wherein the carrier and the lead are configured to block an electromagnetic wave between the electronic component and an external of the electronic device.

2. The electronic device of claim 1, further comprising a connecting element connected to the electronic component through the carrier, wherein the connecting element has a curved surface covered by an encapsulant.

3. The electronic device of claim 1, further comprising an encapsulant encapsulating the carrier and the lead, wherein a portion of the lead is exposed by the encapsulant and a portion of the carrier is exposed by the encapsulant.

4. The electronic device of claim 3, further comprising a protective layer covering the portion of the lead and the portion of the carrier, wherein the protective layer is configured to block the electromagnetic wave between the electronic component and the external of the electronic device.

5. The electronic device of claim 4, wherein the protective layer and the encapsulant comprise a substantially identical material.

6. The electronic device of claim 1, wherein the lead has a curved surface, and the carrier has a curved surface facing the curved surface of the lead.

7. The electronic device of claim 6, wherein the curved surface of the lead and the curved surface of the carrier have different curvatures.

8. The electronic device of claim 2, wherein the connecting element has a first upper surface, a second upper surface, and a first latch structure extending from the first upper surface toward the second upper surface.

9. The electronic device of claim 8, wherein the connecting element has a second latch structure matching a corner of the carrier.

10. The electronic device of claim 9, further comprising an encapsulant encapsulating the electronic component and in contact with the first latch structure and the second latch structure.

11. An electronic device, comprising:
an encapsulant; and
a conductive structure encapsulated by the encapsulant and comprising:
a carrier;
a connecting element supporting the carrier and having a first upper surface exposed from the encapsulant; and
a first lead spaced apart from the connecting element and having a first upper surface exposed from the encapsulant,
wherein an area of the first upper surface of the connecting element is less than an area of the first upper surface of the first lead.

12. The electronic device of claim 11, wherein the connecting element directly contacts the carrier, and the first lead is spaced apart from the carrier.

13. The electronic device of claim 11, wherein a width of the first upper surface of the connecting element is less than a width of the first upper surface of the first lead in a cross-sectional view.

14. The electronic device of claim 11, further comprising a second lead adjacent to the first lead, wherein the first upper surface of the connecting element is between the first lead and the second lead.

15. The electronic device of claim 11, wherein the connecting element has a bottom surface opposite to the first upper surface of the connecting element and exposed by the encapsulant, and an area of the bottom surface is greater than the area of the first upper surface of the connecting element.

16. The electronic device of claim 15, wherein the connecting element has a first edge and a second edge, and the first edge and the second edge overlap the bottom surface of the connecting element in a direction perpendicular to the bottom surface.

17. The electronic device of claim 16, wherein the connecting element has a second upper surface covered by the encapsulant, a first side extending from the first edge to the second upper surface, and a second side extending from the second edge to the second upper surface, and wherein the first side is non-parallel with the second side.

18. An electronic device, comprising:
an electronic component;
an encapsulant encapsulating the electronic component and having a top surface and a lateral surface; and
a lead disposed at a side of the electronic component and having a top surface substantially aligned with the top surface of the encapsulant, a lateral surface substantially aligned with the lateral surface of the encapsulant, a curved surface extending between the top surface of the lead and the lateral surface of the lead.

19. The electronic device of claim 18, wherein the curved surface and the lateral surface of the lead have different surface roughnesses.

20. The electronic device of claim 18, further comprising a carrier supporting the electronic component, wherein the carrier has a top surface substantially aligned with the top surface of the lead.
